(19) United States
(12) Patent Application Publication
(10) Pub. No.: US 2026/0234786 A1
(43) Pub. Date: Aug. 13, 2026

(54) STRUCTURAL MEMBER

(71) Applicant: TOTO LTD., Fukuoka (JP)

(72) Inventors: Kenichi MOTOMURA, Fukuoka (JP); Ryoto TAKIZAWA, Fukuoka (JP); Tatsuya KOGA, Fukuoka (JP); Yasutaka NITTA, Fukuoka (JP)

(73) Assignee: TOTO LTD., Fukuoka (JP)

(21) Appl. No.: 19/533,698

(22) Filed: Feb. 9, 2026

(30) Foreign Application Priority Data
Feb. 10, 2025 (JP) 2025-019767

(51) Int. Cl. C23C 14/08

(52) U.S. Cl. CPC C23C 14/083

(57) ABSTRACT

A structural member 10 includes: a base material 100; and a protective film 200 that is a film covering a surface 110 of the base material 100 and contains polycrystalline yttria as a main component. When an average value calculated from the particle diameters of crystal particles CP of yttria appearing in a cross-section given by slicing the protective film 200 along a plane parallel to a surface 110 of the base material 100 with weighting by the cross-sectional areas of the crystal particles CP is defined as an average diameter, and a part of the protective film 200 proximity to a surface 210 of the protective film 200 opposite to the base material 100 is defined as a shallow part 201, the average diameter in the shallow part is 80 nm or more.

### CROSS-REFERENCE TO RELATED APPLICATION

This application is based upon and claims the benefit of priority from Japanese Patent Application No. 2025-019767 filed on Feb. 10, 2025, the entire contents of which are incorporated herein by reference.

### FIELD

The present invention relates to a structural member.

### BACKGROUND

Structural members having a protective film on a surface of a base material are used in various fields including semiconductor production apparatuses. For example, as described in Japanese Patent No. 7290716, surfaces of base materials constituting inner walls of chambers in semiconductor production apparatuses have protective films formed thereon to protect the base materials from plasma. For such protective films, for example, oxide ceramics such as yttria are used.

### SUMMARY

As processing of substrates is repeated in a semiconductor production apparatus, protective films therein gradually deteriorate over time. In order to achieve reduced maintenance frequency for semiconductor production apparatuses, it is preferable for protective films to have plasma durability as high as possible.

Japanese Patent No. 7290716 proposes setting the average particle size of crystal particles constituting a protective film within a specific range, for example, for the purpose of increasing the plasma durability of the protective film. However, the particle diameters of crystal particles contained in a protective film are relatively small and largely varied in most cases. Therefore, it is probably difficult to definitely specify the relationship between average particle size, which is the average value of particle diameters, and the plasma durability of a protective film. In other words, it is probably difficult to definitely set such an upper limit value of average particle size that sufficiently ensures the plasma durability of a protective film. Accordingly, forming a protective film having sufficient plasma durability is expected to be difficult even if a conventional index as shown in the above patent literature is used.

The present invention has been made in view of such a problem, and an object of the present invention is to provide a structural member with a protective film having high plasma durability.

To solve the problem, the structural member according to the present invention includes: a base material; and a protective film that is a film covering a surface of the base material and contains polycrystalline yttria as a main component. When an average value calculated from the particle diameters of crystal particles of yttria appearing in a cross-section given by slicing the protective film along a plane parallel to a surface of the base material with weighting by the cross-sectional areas of the crystal particles is defined as an average diameter, and a part of the protective film proximity to a surface of the protective film opposite to the base material is defined as a shallow part, the average diameter in the shallow part in the structural member is 80 nm or more.

Experiments and the like conducted by the present inventors have found that when the “average diameter” calculated with weighting by the cross-sectional areas of crystal particles as just stated is used as a novel index, a more significant correlation is exhibited between the plasma durability of a protective film and the index. It has also been found that sufficient plasma durability can be ensured for a protective film if the protective film is formed to give an average diameter of 80 nm or more in the shallow part.

The present invention can provide a structural member with a protective film having high plasma durability.

### BRIEF DESCRIPTION OF THE DRAWINGS

FIG. 1 is a diagram schematically illustrating a cross-section of a structural member according to an embodiment of the present invention;

FIG. 2 is an enlarged view of part of the cross-section in FIG. 1;

FIG. 3 is a diagram schematically illustrating the III-III cross-section in FIG. 2;

FIG. 4 is a diagram schematically illustrating the IV-IV cross-section in FIG. 2; and

FIG. 5 is a table showing results of testing on plasma durability and others for protective films.

### DETAILED DESCRIPTION

An embodiment of the present invention will be described below with reference to the attached drawings. For easy understanding of the description, identical reference signs are assigned to identical constituents in the drawings as much as possible to omit redundant description.

A structural member 10 according to an embodiment of the present invention is used as a member to constitute inner walls of processing chambers in semiconductor production apparatuses (not shown) such as plasma etching apparatuses. Such an application of the structural member 10 is merely an example, and applications thereof are not limited to semiconductor production apparatuses.

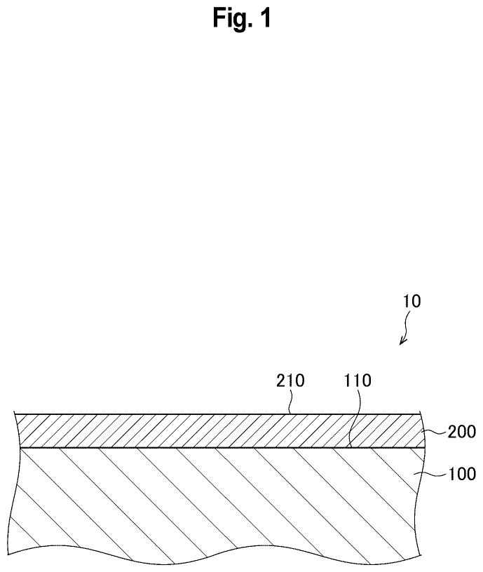

As illustrated in FIG. 1, the structural member 10 includes a base material 100 and a protective film 200. In a plasma etching apparatus or the like, a surface 210 of the protective film 200 is left exposed to the space in a chamber. The protective film 200 is provided for the purpose of protecting a surface 110 of the base material 100 from plasma.

The base material 100 is a member occupying almost the whole of the structural member 10. In the present embodiment, the base material 100 is a sintered body of ceramic containing alumina (Al₂O₃) as a main component, whereas the base material 100 may be a ceramic sintered body of another type. While the surface 110 of the base material 100 is a flat surface in the present embodiment, the surface 110 may be not a flat surface but a curved surface or the like. A slope may be provided in part of the surface 110.

As mentioned above, the protective film 200 is a film formed for protecting the base material 100 from plasma. The protective film 200 has been formed to cover the whole of the surface 110 of the base material 100. The protective film 200 contains polycrystalline yttria (Y₂O₃) as a main component. An appropriate thickness is set for the protective film 200 to match the length of a period during which the durability is required to be maintained. In the present embodiment, the thickness of the protective film 200 is about 5 to 10 μm.

In the present specification, the term “main component” refers to a compound that is found to be relatively abundant as compared with other compounds contained in a target such as the protective film 200 when the target is subjected to quantitative or quasi-quantitative analysis by means of X-ray diffraction (XRD). For example, the term main component refers to a compound that is the most abundant in a target, and the proportion of a main component in a target is more than 50% in a volume ratio or mass ratio. The proportion of a main component in a target is more preferably more than 70%, and a proportion of more than 90% is also preferable. The proportion of a main component may be 100%.

The protective film 200 in the present embodiment has been formed by applying physical vapor deposition (PVD) to the surface 110 of the base material 100 after firing. The protective film 200 may have been formed by another film formation method. For example, the protective film 200 may have been formed by means of chemical vapor deposition (CVD), aerosol deposition, or the like.

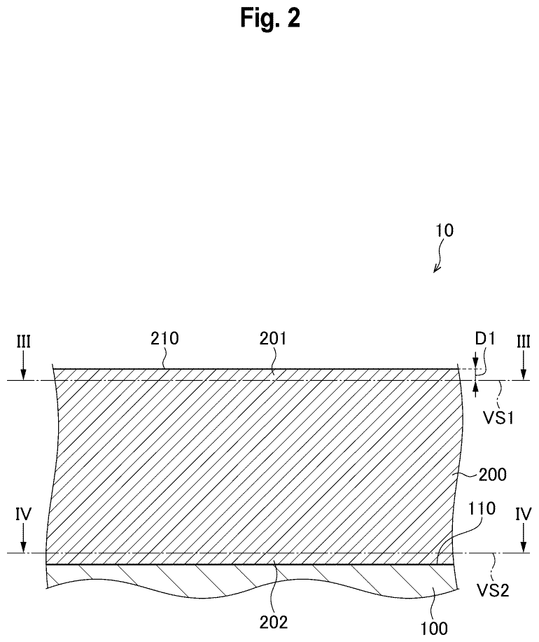

FIG. 2 shows an enlarged view of the cross-section of the protective film 200. In the drawing, the part provided with the reference sign “201” is a part of the protective film 200 proximity to a surface 210 of the protective film 200 opposite to the base material 100. Hereinafter, this part is also referred to as “shallow part 201”. “A part of . . . proximity to the surface 210” is specifically any part of the protective film 200 at a position within a distance of 100 nm from the surface 210.

A plane VS1 indicated with a dash-dot line in FIG. 2 is parallel to the surface 110 of the base material 100, and represents a virtual plane at a distance D1 within 100 nm from the surface 210. The plane VS1 is a plane passing through the shallow part 201.

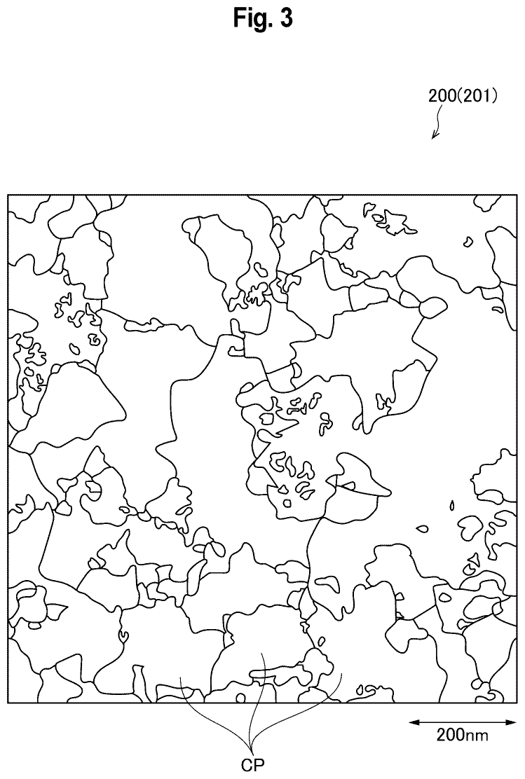

FIG. 3 schematically shows the III-III cross-section in FIG. 2. This cross-section represents a cross-section given by slicing the protective film 200 along the plane VS1, that is, a cross-section of the shallow part 201 of the protective film 200.

The part provided with the reference sign “202” in FIG. 2 is a part of the protective film 200 proximity to a boundary between the protective film 200 and the base material 100 (i.e., the surface 110). Hereinafter, this part is also referred to as “deep part 202”. “A part of . . . proximity to a boundary between . . . and the base material 100” is specifically any part of the protective film 200 at a position within a distance of 1 μm from the surface 110.

A plane VS2 indicated with a dash-dot line in FIG. 2 is parallel to the surface 110 of the base material 100, and represents a virtual plane at a distance D2 within 1 μm from the surface 110. The plane VS2 is a plane passing through the deep part 202.

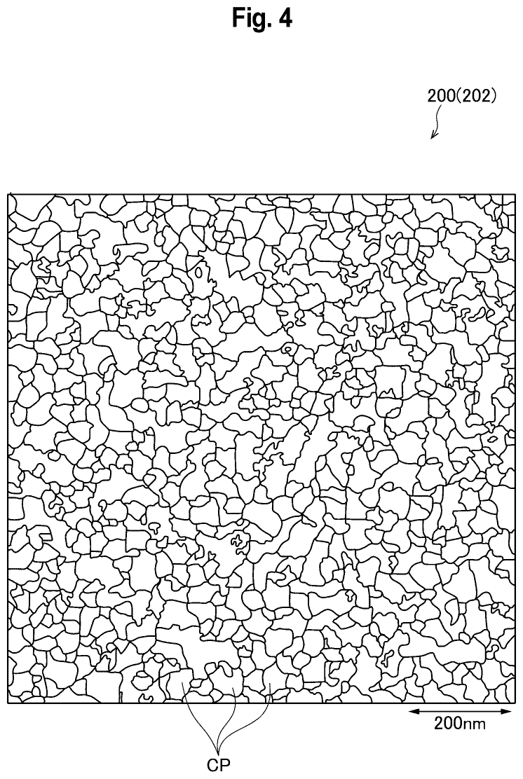

FIG. 4 schematically shows the IV-IV cross-section in FIG. 2. This cross-section represents a cross-section given by slicing the protective film 200 along the plane VS2, that is, a cross-section of the deep part 202 of the protective film 200.

In FIG. 3 and FIG. 4, each region provided with the reference sign “CP” is a crystal particle of yttria appearing in the corresponding cross-section. Hereinafter, such a crystal particle is also referred to as “crystal particle CP”.

As is clear from comparison between FIG. 3 and FIG. 4, the protective film 200 in the present embodiment has relatively large crystal particles CP in the shallow part 201 (FIG. 3), and has relatively small crystal particles CP in the deep part 202 (FIG. 4).

The shallow part 201 of the protective film 200 is a part proximity to the surface 210, which is to be exposed to plasma, hence being a part particularly required to have plasma durability. As in the present embodiment, providing the shallow part 201 with larger crystal particles CP successfully allows the protective film 200 to have enhanced plasma durability. This is probably because the larger the crystal particles CP in the shallow part 201, the smaller the proportion of particle interfaces on the surface 210, which can be the origin of erosion.

It is also contemplated to provide not just the shallow part 201 but the whole of the protective film 200 with large crystal particles CP for allowing the protective film 200 to have enhanced plasma durability. However, as disclosed in “Grain Size Dependence of Fracture Toughness in Polycrystalline Alumina” (HAYASHI Kunio, GOTO Kenichi, NISHIKAWA Tomozo, Journal of the Ceramic Society of Japan 99[7] (1991)), for example, it is known that as the protective film 200 has larger crystal particles CP, the protective film 200 disadvantageously has lower fracture toughness. In particular, the part of the protective film 200 proximity to the surface 110 is a part likely to be subjected to stress due to difference in thermal expansion from the base material 100, and hence it is needed to sufficiently ensure the fracture toughness in that part.

In view of this, the present embodiment employs a configuration in which the shallow part 201 of the protective film 200 is provided with large crystal particles CP to allow the part to have enhanced plasma durability, and conversely the deep part 202 is provided with small crystal particles CP to allow the part to have enhanced fracture toughness. This configuration allows the protective film 200 to have enhanced plasma durability and at the same time successfully prevents the break of the protective film 200 due to difference in thermal expansion from the base material 100.

On the basis of those findings, the present inventors examined on use of the average value of the particle diameters of crystal particles CP as an index of the size of crystal particles CP in each part of the protective film 200. For example, forming the protective film 200 with setting a lower limit value for an acceptable range of the average value of the particle diameters of crystal particles CP in the shallow part 201 was expected to successfully allow the protective film 200 to have high plasma durability. Likewise, forming the protective film 200 with setting an upper limit value for an acceptable range of the average value of the particle diameters of crystal particles CP in the deep part 202 was expected to successfully prevent the break of the protective film 200 due to difference in thermal expansion.

However, the particle diameters of crystal particles CP contained in the protective film 200 are relatively small and largely varied in most cases. Therefore, it was difficult to definitely specify the relationship between the average value of the particle diameters of crystal particles CP and the plasma durability of the protective film 200. In other words, it was difficult to properly set an upper limit value and lower limit value as mentioned above for the average value of the particle diameters of crystal particles CP.

Accordingly, the present inventors diligently continued examination for a novel index as an alternative to the (simple) average value of the particle diameters of crystal particles CP. As a result, we eventually devised “average diameter” defined by the following expression (1) as an unprecedented, novel index.

### Expression 1

“Sᵢ” on the right-hand side of the expression (1) denotes the cross-sectional area of the respective crystal particle CP in a cross-section as shown in FIG. 3. “Dᵢ” denotes the particle diameter of the respective crystal particle CP in the same cross-section. Here, the term “particle diameter” refers to the diameter of an approximate circle for a crystal particle CP. Particle diameter has a unit of, for example, “nm (nanometer)”.

The numerator on the right-hand side of the expression (1) represents the sum total of values of Sᵢ×Dᵢ for all crystal particles CP present in a range of specific area in a cross-section as shown in FIG. 3. The denominator on the right-hand side of the expression (1) represents the sum total of values of Sᵢ for all crystal particles CP present in a range of specific area in a cross-section as shown in FIG. 3. In the present embodiment, a range of 1 μm×1 μm was used as the “range of specific area”.

The “average diameter” calculated with the expression (1) can be defined as an average value calculated from the particle diameters of crystal particles CP of yttria appearing in a cross-section given by slicing the protective film 200 along a plane parallel to the surface 110 of the base material 100 with weighting by the cross-sectional areas of the crystal particles CP. In the present embodiment, the average diameter calculated for the cross-section shown in FIG. 3 and the average diameter calculated for the cross-section shown in FIG. 4 are different from each other.

The present inventors produced multiple samples of a structural member 10 with protective films 200 different from each other in terms of crystal structure and other properties, and the protective films 200 of the samples were subjected to evaluation on plasma durability and other operations. This experiment revealed, for example, the relationship between the average diameter at a specific position of a protective film 200 and the plasma durability of the protective film 200.

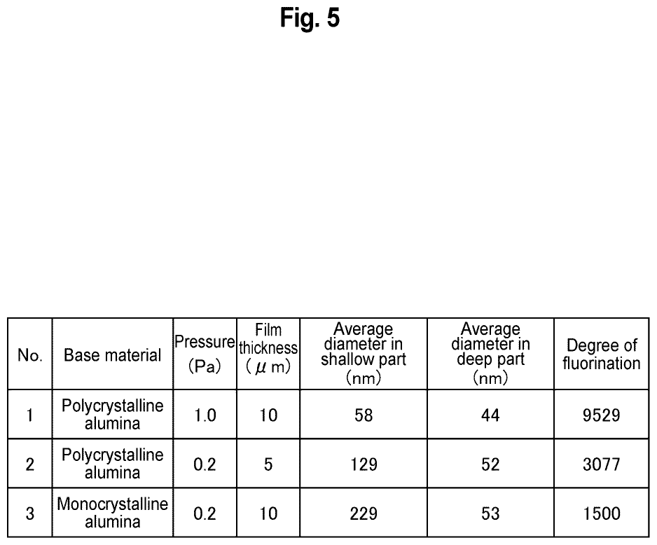

Production conditions, evaluation results, and others for the samples will be explained with reference to the table in FIG. 5. The samples shown as “No.1”, “No.2”, and “No.3” in the table were produced by forming a protective film 200 on a surface 110 of a base material 100 containing alumina as a main component by means of physical vapor deposition. For the samples of “No.1” and “No.2”, polycrystalline alumina was used as a base material 100. For the sample of “No.3”, monocrystalline alumina (sapphire with the C-plane thereof corresponding to a surface 210) was used. Nos. 2 and 3 are samples according to the present embodiment, and No. 1 is a sample of a comparative example.

The column “Pressure” in FIG. 5 shows pressure, specifically, pressure of argon, in a film-formation chamber in forming each protective film 200 with a unit of “Pa”. The column “Film thickness” shows total thickness for the protective films 200 with a unit of “μm”.

The column “Average diameter in shallow part” shows values of average diameter calculated for cross-sections of the shallow parts 201 with a unit of “nm”. For every sample, D1, the distance between a cross-section to be used for calculation of average diameter in the shallow part 201 and the surface 210, was set to 100 nm.

The column “Average diameter in deep part” shows values of average diameter calculated for cross-sections of the deep parts 202 with a unit of “nm”. For every sample, D2, the distance between a cross-section to be used for calculation of average diameter in the deep part 202 and the surface 110, was set to 1 μm.

For each sample, average diameters were calculated in a manner as follows. First, from the protective film 200 of each sample, a part at a position at a distance D1 of 100 nm from the surface 210 was cut out by using a focused ion beam (FIB) method. The size of the cut piece was 1 μm×1 μm×50 nm. Subsequently, the principal surface (the surface of 1 μm×1 μm) of the cut piece was entirely observed with a transmission electron microscope. The transmission electron microscope used was a JEM-ARM200F manufactured by JEOL Ltd. the acceleration voltage was set to 200 kV.

With an image obtained through the observation, acquisition and processing of data were performed by using a crystal orientation analysis system. Through the processing, the forms of crystal particles CP (forms, for example, as shown in FIG. 3) appearing in the image are automatically specified, and values of cross-sectional area (Sᵢ) and values of particle diameter (Dᵢ) for crystal particles CP are individually calculated. On the basis of those values and the expression (1), values of “Average diameter in shallow part” were calculated. The crystal orientation analysis system used was an ASTAR manufactured by NanoMegas.

The same calculation method as just explained is used for “Average diameter in deep part”. From each protective film 200, a part at a position at a distance D2 of 1 μm from the surface 110 was cut out by using a focused ion beam (FIB) method, and the resulting piece was subjected to observation and other operations in the same manner as explained above.

As shown in FIG. 5, in the sample of No.1, the average diameter in the shallow part was 58 nm and the average diameter in the deep part was 44 nm. In the sample of No. 2, the average diameter in the shallow part was 129 nm and the average diameter in the deep part was 52 nm. In the sample of No. 3, the average diameter in the shallow part was 229 nm and the average diameter in the deep part was 53 nm.

The present inventors conducted evaluation test on plasma durability for the samples of Nos. 1 to 3. This test was conducted for other samples produced under the same conditions for the samples used for measurement of “Average diameter in shallow part” and other properties.

In evaluation of the durability of each protective film 200, the surface 210 of the protective film 200 was exposed to a plasma atmosphere by using an inductively coupled plasma reactive ion etching (ICP-RIE) apparatus which is not shown. The following conditions were used in exposing the surface 210 to a plasma atmosphere.

First, a silicon wafer of 4 inches in size was held by adsorption with an electrostatic chuck in a chamber of the inductively coupled plasma reactive ion etching apparatus. Subsequently, a sample of a structural member 10 to be evaluated was placed on the silicon wafer. After that, the surface 210 of the protective film 200 was exposed to a plasma atmosphere by generating plasma in the chamber. SF₆ was used as process gas, and the gas was fed into the chamber at a flow rate of 100 sccm. The pressure in the chamber was adjusted to 0.5 Pa. The exposure time was 30 minutes. For the magnitudes of power outputs, a coil output of 1500 W was used for ICP, and a bias output of 750 W was used. Use of a bias output of 750 W allows plasma to be drawn toward the protective film 200 and provided for etching of the protective film 200.

Each value shown in the column “Degree of fluorination” in FIG. 5 is an index of degree of intrusion of fluorine atoms into the protective film 200 after the protective film 200 has been exposed to a plasma atmosphere as explained above. The specific calculation method for degree of fluorination is as follows.

First, a surface 210 of a protective film 200 exposed to a plasma atmosphere as explained above was subjected to continuous measurement of the amount of fluorine atoms present on the surface 210 by means of X-ray photoelectron spectroscopy (XPS) while sputtered with argon. The measurement was performed over 145 seconds. At that time, the proportion of measurements for argon (unit: %) was calculated at each time, and a cumulative value of the obtained values was calculated as the “Degree of fluorination” of the sample. The higher the plasma durability of a protective film 200 is, the smaller the value of degree of fluorination calculated is as just explained. Degree of fluorination can be used as an index of the plasma durability of a protective film 200.

The sample of No. 1, which was a sample in which the average diameter in the shallow part was as small as less than 80 nm, was found to have very high degree of fluorination and thus low plasma durability. By contrast, the samples of Nos. 2 and 3, which were samples in each of which the average diameter in the shallow part was as large as 80 nm or more, were found to have low degree of fluorination and thus sufficient plasma durability.

Thus, in the structural member 10 according to the present embodiment (Nos.2, 3), the average diameter in the shallow part 201 of the protective film 200 is 80 nm or more, and the structural member 10 have high plasma durability. In the structural member 10 according to the present embodiment, the average diameter in the deep part 202 of the protective film 200 is 70 nm or less, and as a result the part has enhanced fracture toughness, and the break of the protective film 200 due to difference in thermal expansion from the base material 100 is prevented.

While a value of 80 nm or more is sufficient for the average diameter in the shallow part 201 as explained above, employing a value of 100 nm or more therefor as in the present embodiment successfully allows the protective film 200 to have much higher plasma durability. While a value of 70 nm or less is sufficient for the average diameter in the deep part 202 as explained above, employing a value of 60 nm or less therefor as in the present embodiment successfully allows the part to have much higher fracture toughness.

The shallow part 201 satisfying the condition as shown above can be present at any position of the protective film 200 within a distance of 100 nm from the surface 210. Likewise, the deep part 202 satisfying the condition as shown above can be present at any position of the protective film 200 within a distance of 1 μm from the surface 110.

The average diameters at different levels of the protective film 200 may show gradual increase from the base material 100 to the surface 210, and otherwise may show stepwise (i.e., discontinuous) changes in the course.

For forming the protective film 200 with the average diameter in the shallow part 201 and the average diameter in the deep part 202 differing from each other, for example, a method of decreasing the pressure of argon in a chamber during film formation over time may be employed. Alternatively, a method of discontinuously changing the feeding rate or type of gas during film formation may be employed.

Thus, the present embodiment has been explained with reference to specific examples. However, the present disclosure is not limited by those specific examples. Embodiments given by those skilled in the art by adding design modification to any of the specific examples are included in the scope of the present disclosure, as long as the embodiments possess the features of the present disclosure. Elements to be included, and arrangement, conditions, forms, and others for the elements are not limited to those of the specific examples shown above, and appropriate modification can be made. The combination of elements included in each of the specific examples shown above can be appropriately changed, unless any technical inconsistency arises.

What is claimed is:

1. A structural member comprising:
a base material; and
a protective film that is a film covering a surface of the base material and contains polycrystalline yttria as a main component, wherein
an average diameter in a shallow part is 80 nm or more, wherein
the average diameter is an average value calculated from particle diameters of crystal particles of yttria appearing in a cross-section given by slicing the protective film along a plane parallel to a surface of the base material with weighting by cross-sectional areas of the crystal particles, and
the shallow part is a part of the protective film proximity to a surface of the protective film opposite to the base material.

2. The structural member according to claim 1, wherein the average diameter in the shallow part is 100 nm or more.

3. The structural member according to claim 1, wherein the shallow part is a part of the protective film at a position within a distance of 100 nm from the surface of the protective film opposite to the base material.

4. The structural member according to claim 2, wherein the shallow part is a part of the protective film at a position within a distance of 100 nm from the surface of the protective film opposite to the base material.

5. The structural member according to claim 1, wherein the average diameter in a deep part is 70 nm or less, wherein
the deep part is a part of the protective film proximity to a boundary between the protective film and the base material.

6. The structural member according to claim 5, wherein the average diameter in the deep part is 60 nm or less.

7. The structural member according to claim 5, wherein the deep part is a part of the protective film at a position within a distance of 1 μm from the boundary between the protective film and the base material.

8. The structural member according to claim 6, wherein the deep part is a part of the protective film at a position within a distance of 1 μm from the boundary between the protective film and the base material.

9. The structural member according to claim 1, wherein the protective film is a film formed by means of physical vapor deposition.

10. The structural member according to claim 1, wherein the base material contains alumina as a main component.
